(19) United States
(12) Patent Application Publication
(10) Pub. No.: US 2022/0113868 A1
(43) Pub. Date: Apr. 14, 2022

(54) MITIGATING ROW-HAMMER ATTACKS

(71) Applicant: Microsoft Technology Licensing, LLC, Redmond, WA (US)

(72) Inventors: Tim COWLES, Boise, ID (US); Terry M. GRUNZKE, Boise, ID (US); Brett Kenneth DODDS, Boise, ID (US); Todd Alan MERRITT, Boise, ID (US); Gary Lee VAN ACKERN, Meridian, ID (US)

(21) Appl. No.: 17/067,349

(22) Filed: Oct. 9, 2020

(51) Int. Cl. G06F 3/06

(52) U.S. Cl. CPC G06F 3/062; G06F 3/0671; G06F 3/0653

(57) ABSTRACT

A computing apparatus in an implementation comprises a memory device and a controller. The memory device comprises banks of cells arranged in rows and columns and is configured to maintain a row-level activation count on a per-row basis. The controller is operatively coupled with the memory device and is configured to maintain a bank-level activation count on a per-bank basis. The controller initiates a refresh operation for at least a given row in the memory device when at least both the bank-level activation count for a given bank satisfies a bank-level condition, and the row-level activation count for the given row satisfies a row-level condition.

### TECHNICAL FIELD

Aspects of the disclosure are related to the field of computing, and in particular, to microprocessors and memory devices.

### TECHNICAL BACKGROUND

Modern dynamic random-access memory (DRAM) chips with small dimensions have disturbance effects where operations on one row may corrupt the values in adjacent or nearby rows. This creates both reliability and security problems, which are increasing in severity as DRAM designs shrink, and that have proven exceedingly difficult to solve. The security issues in particular are concerns for DRAM vendors, and for DRAM users.

A row-hammer attack is one such exploitation that executes repeated reads on an aggressor row in memory with the intention of changing the values in nearby or adjacent rows. The repeated reads of the aggressor row cause charge to leak from the cells in the aggressor row to the cells in the victim rows. Refresh operations, which are performed periodically on DRAM chips for the purpose of protecting against normal charge loss, are not performed frequently enough to fully mitigate the risk posed by row-hammer attacks. Increasing the frequency of refresh operations is one technique for mitigating row-hammer attacks but can take upwards of 30-40% of system bandwidth depending on the workload of the system. This is an unacceptable solution for any server or compute resource where performance is a main metric.

Other solutions include monitoring relatively small sets of high activity rows, as well as attempting to interfere with instruction sequences that can generate fast changes. Both of these approaches are unsatisfactory because the algorithms used to track high activity rows can be circumvented by clever patterns, while it is difficult to block instruction sequences without having an impact on valid high-performance programs. Additional complications include an industry desire to have a single, broadly effective solution so that DRAM remains a single commodity with broad markets (ensuring best costs).

### Overview

Technology is disclosed herein that mitigates the risks posed by certain security exploits such as row-hammer attacks. A computing apparatus in an implementation comprises a memory device and a controller. The memory device comprises banks of cells arranged in rows and columns. The memory device is configured to maintain a row-level activation count on a per-row basis. The controller is operatively coupled with the memory device and is configured to maintain a bank-level activation count on a per-bank basis. The controller initiates a refresh operation for at least a given row in the memory device when at least both the bank-level activation count for a given bank satisfies a bank-level condition, and the row-level activation count for the given row satisfies a row-level condition.

This Overview is provided to introduce a selection of concepts in a simplified form that are further described below in the Technical Disclosure. It may be understood that this Overview is not intended to identify key features or essential features of the claimed subject matter, nor is it intended to be used to limit the scope of the claimed subject matter.

### BRIEF DESCRIPTION OF THE DRAWINGS

Many aspects of the disclosure may be better understood with reference to the following drawings. The components in the drawings are not necessarily to scale, emphasis instead being placed upon clearly illustrating the principles of the present disclosure. Moreover, like reference numerals in the drawings designate corresponding parts throughout the several views. While several implementations are described in connection with these drawings, the disclosure is not limited to the implementations disclosed herein. On the contrary, the intent is to cover all alternatives, modifications, and equivalents.

FIG. 1 illustrates a computing environment in an implementation.

FIG. 2 illustrates a sub-environment in an implementation.

FIG. 3 illustrates a host-side attack mitigation process in an implementation.

FIG. 4 illustrates a device-side attack mitigation process in an implementation.

FIG. 5 illustrates an operational scenario in an implementation.

FIG. 6 illustrates an operational scenario in an implementation.

FIG. 7 illustrates an operational scenario in an implementation.

### DETAILED DESCRIPTION

Technology disclosed herein relates to improvements to computing environments that enhance their ability to withstand certain security exploits without suffering unacceptable declines in performance. In various implementations, the memory devices in a computer maintain row-level activation counts on a per-row basis, while the memory controller maintains a bank-level activation count on a per-bank basis. The controller initiates a refresh operation for at least a given row in a memory device when at least both the bank-level activation count for a given bank satisfies a bank-level condition, and the row-level activation count for the given row satisfies a row-level condition at the same time. Such an approach has the technical effect of mitigating row-hammer attacks by refreshing one or more rows, while avoiding an unacceptable decline in performance associated with conducting refresh operations too frequently.

In some implementations, a memory device requests a refresh when the activation count for a row satisfies a row-level condition such as a threshold (e.g. meets or exceeds a threshold). The refresh may be “requested” by way of a pin set by circuitry in the memory device that is readable by the memory controller. In other examples, a memory device may set a flag at a location readable by the memory controller. In both cases, the memory device sets the pin or flag in response to the threshold condition being met.

In another example, the memory device requests a refresh by adjusting a refresh parameter that indicates to the controller how frequently to initiate refresh operations. The refresh parameter is a value that the controller counts down and that, at its expiration, triggers the controller to initiate a refresh of the subject row(s). A memory device can adjust the refresh parameter down so that, when the controller reads it, the lower value causes the controller to initiate a refresh on certain rows earlier than it otherwise would have.

The memory controller may be implemented in the context of a microprocessor, examples of which include central processing units, graphical processing units, and the like. The memory controller tracks on a per-bank basis how many times a bank has been activated. In the past, a controller would initiate a refresh on a bank of memory cells once the activation count for a given bank had exceeded a threshold, resulting in too many time-consuming refresh operations that wasted bandwidth. Instead, the memory controllers disclosed herein check with the memory when bank-level activations indicate that an attack may be underway. The controllers refrain from initiating a refresh until the memory devices confirm.

As mentioned, the memory devices confirm conditions upon which a refresh may be initiated by setting a pin, writing a flag, adjusting a parameter, or otherwise requesting a refresh operation. The controllers contemplated herein “receive” the requests by detecting a high (or low) value on the pin, reading a bit value of the flag, or responding to the newly adjusted parameter as dictated by their refresh algorithms. A controller configured as such responsively sends a refresh command to an affected memory device to recharge the affected cells.

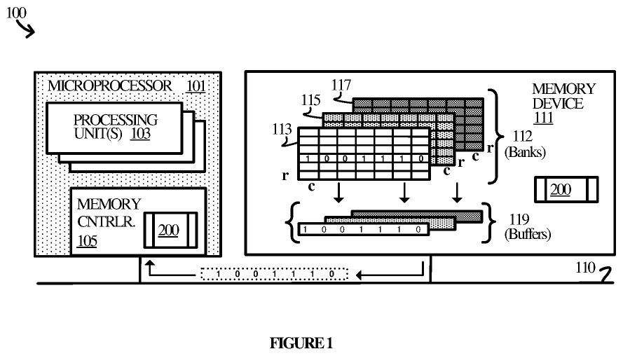

Referring to the drawings, FIG. 1 illustrates a computing environment 100 in an implementation, examples of which include server computers, desktop computers, laptop computers, tablets, mobile devices, Internet of Things (IoT) devices, and the like. Computing environment 100 includes microprocessor 101 and memory device 111 connected via channel 110, examples of which include a data bus, a memory bus, or any other suitable interface.

Microprocessor 101 includes processing unit 103 and memory controller 105. Processing unit 103 is representative of one or more hardware elements that allow microprocessor 101 to execute instructions and process data. Examples of processing unit 103 include, but are not limited to: registers, program counters, arithmetic logic units, accumulators, and control units. Memory controller 105 is representative of one such control unit that governs the flow of program instructions and data between microprocessor 101 and memory device 111.

Memory controller 105 includes various logic elements that provide control over the exchange of data between microprocessor 101 and memory device 111. Operations conducted by memory controller 105 include, but are not limited to, refresh operations, read/write operations, interleaving, buffering, error checking and correcting (ECC) operations, and page open/close operations. Memory controller 105 may also govern memory bus initialization, characterization, and timing configuration during boot; read/set configuration registers in memory devices; and determine/adjust voltage levels, power levels, latency, and clock speeds. The logic governing such aspects of memory controller 105 may be implemented in control circuitry such as field-programmable gate array (FPGA) circuitry, application specific integrated circuits (ASICs), or other such integrated circuits.

Memory device 111 is representative of one or more random access memory (RAM) devices capable of storing program instructions and data, examples of which include dynamic random-access memory (DRAM) chips. Memory device 111 may be configured with one or more other memory devices to form a rank, which itself can be grouped with one or more other ranks to form a memory module (e.g. a dual in-line memory module, or DIMM). It may be appreciated that computing environment 100 includes only a single memory device for purposes of illustration, whereas most implementations would include multiple memory devices. In some implementations, memory device 111 comprises a synchronous dynamic random-access memory (SDRAM) device implemented in accordance with a double data rate (DDR) memory protocol or any variation thereof such as DDR2, DDR3, DDR4, DDR5, LPDDR, GDDR. The techniques discussed herein also apply to other memory technologies and protocols and not limited to those disclosed herein.

DRAM chips are generally composed of large arrays of cells arranged in rows and columns, called word-lines and bit-lines respectively. DRAM also includes support circuitry for reading data out from the memory cells, writing data to the memory cells, and for refreshing the DRAM circuitry to maintain the integrity of the data. It may be appreciated that, as used herein, the term data includes program instructions as well as any other type of data.

Memory cells include capacitors that are charged to store either a one or a zero. The support circuitry on a chip includes various elements that allow the ones and zeros to be written to or read from the memory cells such as sense amplifiers, row-address-select (RAS) logic, column-address-select logic (CAS), and read and write circuitry. The circuitry also includes internal counters and registers to track refresh sequences and to initiate refresh cycles as needed.

Memory device 111 includes banks 112 of memory cells arranged in arrays of rows and columns, of which bank 113, bank 115, and bank 117 are representative. Each bank may include one or more arrays. Data is written into and read out from the rows of each of the banks 112 and into a corresponding one of buffers 119. That is, bank 113 corresponds to one of the buffers 119, while bank 115 corresponds to another, and so on. In the case of a read operation, data is moved into a buffer and then sent via memory controller 105 to processing unit 103. In the reverse, data is written out of microprocessor 101 to a buffer and then loaded into a row of cells.

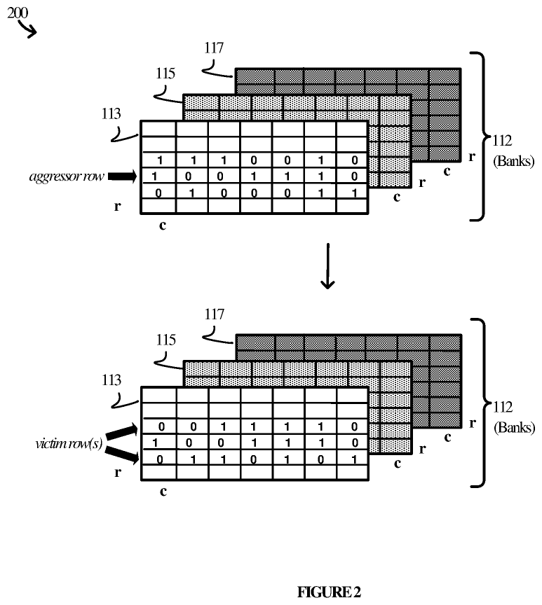

The cells in the memory banks are susceptible to row-hammer attacks and possibly other exploits that take advantage of the disturbance effects that hamper cells. FIG. 2 illustrates one such attack with respect to environment 200, which is a sub-environment of computing environment 100 in FIG. 1. Environment 200 includes banks 112 in a first state where a row in bank 113 is being exploited. The row serves as an aggressor row that is read repeatedly to cause a disturbance in the charge of its adjacent or nearby rows. Such disturbances have the potential to change the actual values in the cells of the victim rows which can cause damage in the wider computing environment. For example, encryption keys could be scrambled, parameters could be changed, and other such data could be corrupted. FIG. 2 briefly illustrates the aggressor row, victim rows, and how the actual values in the victim rows can change.

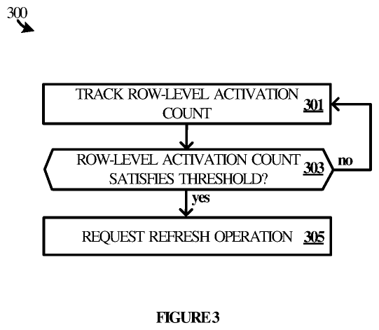

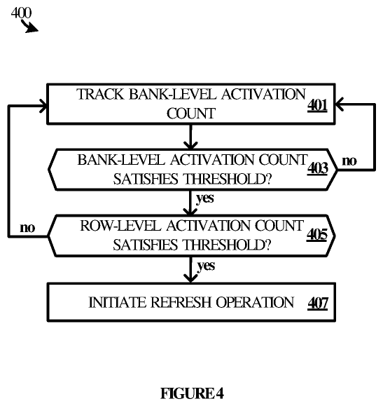

An attack mitigation technique is disclosed herein to reduce the risk presented by such attacks. The attack mitigation process includes two sub-processes: one implemented on the device-side of an environment (sub-process 300 in FIG. 3) and the other on the host-side (sub-process 400 in FIG. 4). Together, the sub-processes function to both leverage the benefits of refresh operations while limiting the drag on bandwidth posed by the same operations. The attack mitigation technology as disclosed herein may be implemented entirely in hardware, entirely in software (including firmware, resident software, micro-code, etc.), or as a combination of hardware and software.

Referring parenthetically to the steps in FIG. 3, a memory device configured in accordance with sub-process 300 (e.g. memory device 111) operates as follows. To begin, the memory device receives read and write instructions from a memory controller to read-out data from memory or write data to memory. To write to a memory cell, the row and column address for the cell is selected and data is presented at the data input pins. The chip's logic either charges or discharges the capacitor in a memory cell, depending on whether a one or a zero is to be stored. To read the data from a memory cell, the cell is selected by its row and column coordinates, the charge on the cell is sensed, amplified, and sent to the support circuitry, and the data is sent to the data output.

Paying particular attention to the read requests, each request pertains to a particular row of cells in a particular bank of memory. The row must be activated in order for the values in its cells to be transferred to a buffer and, from there, read-out to the processor. The memory device maintains a row-level activation count that tracks how many times a row has been activated (step 301). In some implementations, the row-level activation count is a value stored in each row that is incremented each time a given row is activated. The value may be read out from the cell when the row is activated, loaded into a register, incremented, and then stored back into its location in the row. The value (counter) may be reset when the row is refreshed. In other implementations, the row-level activation count may be maintained in a separate location other than the row to which it pertains. In both cases, it may be appreciated that a separate counter is maintained for each row.

Each time a row is activated, the memory device increments the count for that row and checks if the incremented count satisfies row-level condition such as a threshold (step 303). The device may read the value of the row-level activation count while it resides in a register where it was incremented. The device can compare the incremented count to a threshold value that is stored elsewhere in the device such as another register. In some cases, the threshold value may also reside in cells of the same row or elsewhere in memory and can be loaded into another register to compare against the incremented count. In still other implementations, the row-level activation count may be maintained in a circuit connected to each row that increments the count. Upon the count exceeding a threshold, the circuit may trigger yet another circuit to populate a flag, set a pin, or the like, to indicate the row-level activation count has exceeded the threshold.

The logic returns to the start if the row-level activation count fails to satisfy a threshold, or the count triggers a refresh request. Assuming the threshold has been met, the memory device requests a refresh operation on at least the affected cell by, for example: setting a pin, setting a flag, or adjusting a parameter (step 305), any of which signal to the memory controller that a refresh is needed to mitigate the effects of too many reads on a row.

In a complimentary and/or coordinated manner, and referring parenthetically to the steps in FIG. 4, a memory controller configured in accordance with sub-process 400 (e.g. memory controller 105) operates as follows. To begin, the memory controller maintains a count of activations on a per-bank basis (step 401). That is, the memory controller can track how many times a particular bank has been activated since its last refresh but cannot track which specific rows within a bank have been activated. The bank-level activation counts (or counters) are values stored in registers or memory internal to memory controller.

After each increment, the memory controller at step 403 determines whether the bank-level counter has satisfied the threshold. The threshold may also be stored in a register or a location in memory on-board the controller. The determination may be made by comparing a bank-level activation count to the threshold value to determine if the count meets, exceeds, or otherwise satisfies the threshold. The comparison logic can be implemented in firmware on the controller, in circuitry, or in some other manner.

If the bank-level activation count does not satisfy the threshold, then the controller continues to increment the counter each time a row in the bank is activated. However, a series of read operations directed to a group of rows in the same bank could possibly trigger an unnecessary refresh based solely on the bank-level activation count. Thus, in the case where the bank-level activation count satisfies the threshold (step 403), the memory controller proceeds to determine if a row-activation count for a row in the subject bank has also satisfied its threshold (step 405). That is, the memory controller checks to see if the memory device of the subject bank has requested a refresh operation by sensing the pin, reading the flag, and the like. Assuming so, the memory controller initiates a refresh operation (step 407). In some cases, the memory controller initiates the refresh operation by sending a refresh command to the memory device.

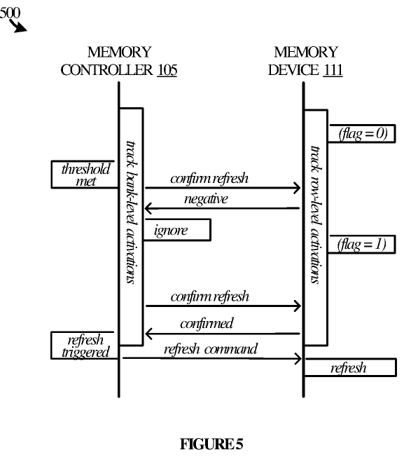

FIG. 5 illustrates an operational scenario 500 to better demonstrate the application of sub-processes 300 and 400 with respect to computing environment 100. In operation, memory controller 105 begins to track bank-level activations for each bank in memory device 111 (as well as other banks on other devices). At the same time, memory device 111 is tracking activations on a row-by-row basis and initially has a flag set in memory to zero, which indicates that no refresh is needed.

At a next point in time, and after a number of bank-level activations, a bank-level activation count tracked by memory controller 105 meets the threshold. This event causes memory controller 105 to check with memory device 111 as to whether a refresh has been requested at this time. The negative is assumed for exemplary purposes, as evidenced by the zero value in the location in memory checked by the controller. Memory controller 105 therefore proceeds to ignore its own refresh alert and instead continues to count activations.

In the meantime, the row-level activation count has met its threshold, causing memory device 111 to change the flag value to one, thereby indicating to memory controller 105 that a refresh is requested. The next time a refresh is triggered by the bank-level activation count, memory controller 105 checks the value of the flag and determines that the refresh has been confirmed. Accordingly, memory controller 105 sends a refresh command to memory device 111 to initiate a refresh of one or more affected rows in the subject bank.

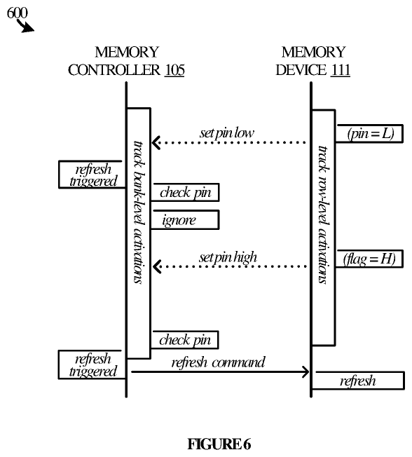

FIG. 6 illustrates another operational scenario 600 to demonstrate the application of sub-processes 300 and 400 with respect to computing environment 100. In operation, memory controller 105 begins to track bank-level activations for each bank in memory device 111 (as well as other banks on other devices). At the same time, memory device 111 is tracking activations on a row-by-row basis and initially has a pin to low, which indicates that no refresh has been requested.

At a next point in time, and after a number of bank-level activations, a bank-level activation count tracked by memory controller 105 meets the threshold. This event causes memory controller 105 to check the state of the pin to determine whether a refresh has been requested at this time. The negative is assumed for exemplary purposes, as evidenced by the low state of the pin. Memory controller 105 therefore proceeds to ignore its own refresh alert and instead continues to count activations.

In the meantime, the row-level activation count has met its threshold, causing memory device 111 to change the pin state to assert high, thereby indicating to memory controller 105 that a refresh is requested. The next time a refresh is triggered by the bank-level activation count, memory controller 105 checks the pin and determines that the refresh has been confirmed. Accordingly, memory controller 105 sends a refresh command to memory device 111 to initiate a refresh of one or more affected rows in the subject bank.

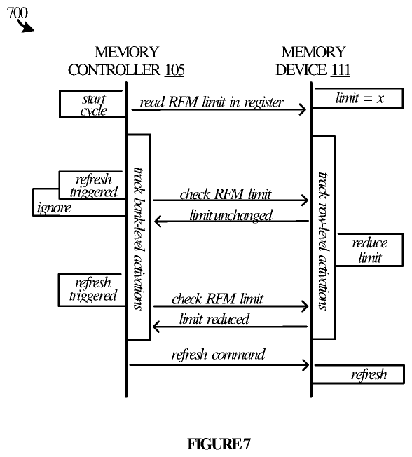

FIG. 7 illustrates yet another operational scenario 700 to demonstrate the application of sub-processes 300 and 400 with respect to computing environment 100. In operation, memory controller 105 reads a refresh management (RFM) parameter from a register in memory device 111. The parameter, which is initially set to “x,” governs how frequently the memory controller 105 initiates refresh operations under normal operating conditions.

Memory controller 105 begins to track bank-level activations for each bank in memory device 111 (as well as other banks on other devices). Memory device 111 is also tracking activations on a row-by-row basis. At a next point in time, and after a number of bank-level activations, a bank-level activation count tracked by memory controller 105 meets the threshold. This event causes memory controller 105 to check the value of the RFM limit in memory device 111. If the limit remains unchanged, and if the subject bank is not yet due for a refresh per the limit, then memory controller 105 ignores the alert triggered by the bank-level activation count. The negative is assumed for exemplary purposes and memory controller 105 therefore proceeds to ignore its own refresh alert and instead continues to count activations.

In the meantime, the row-level activation count has met its threshold, causing memory device 111 to reduce the value of the RFM limit in its register. The next time a refresh is triggered by the bank-level activation count, memory controller 105 reads the RFM limit from the register and updates its refresh algorithm with the new limit. If the limit has been sufficiently reduced, then the algorithm determines that a refresh is needed. Accordingly, memory controller 105 sends a refresh command to memory device 111 to initiate a refresh of one or more affected rows in the subject bank.

In some examples, memory device 111, in addition to banks of memory cells arranged in rows and columns, includes an activation module and a tracking module, both of which may be implemented in hardware (circuitry), firmware, or a combination of both. The activation module is configured to maintain a row-level activation count for at least a row in the bank of memory cells, while the tracking module configured to request a refresh operation, for at least a given row in the banks of memory cells, when the row-level activation count for the given row satisfies a row-level condition.

It may be appreciated the improved refresh management (RFM) disclosed herein provides a variety of technical effects. RFM generally works on a per bank basis and assumes worst-case workloads when counting the number of activate commands sent to each bank, but not every workload that triggers a refresh command warrants one. Unfortunately, existing DRAM and CPU/host solutions are incapable of communicating whether a read pattern actually warrants the RFM command. The improved RFM contemplated herein provides a handshake/indicator that a DRAM chip supplies and that is read by CPU/host (memory controller). The indicator serves as a request by the DRAM for the CPU/host to send an extra RFM command (outside of the normal cycle of RFM operations) to deal with a potential attack. The request is made if the DRAM has identified a type of workload that puts it at risk for the flipping of bits and data loss associated with row-hammer attacks.

The number of extra RFM commands made under the proposed solution is therefore less than what otherwise would occur if the memory controller sent extra RFM commands whenever triggered by a bank-level activation count. That is, using only a bank-level activation count leads to an extraneous number of RFM commands that results in an unnecessary drag on performance. Reducing (or eliminating) extraneous RFM commands therefore provides a relative boost in performance (e.g. speed, latency, energy consumption).

As mentioned, current industry solutions take up to 30-40% of system bandwidth if activity within DRAM is targeting a single bank of memory. Such behavior is not so abnormal that it necessitates refresh operations, especially in the context of workloads related to video streaming, gaming, and the like. As such, the majority of traffic in a bank will not result in needing the RFM command even if bank-level activations are high. Rather, the disclosed techniques allow for row-hammer mitigation only if the DRAM can confirm that the workload causing bank-level activations to go high is also causing a spike in row-level activations. In this manner, the 30-40% system slow-down caused by refresh operations can be avoided when they are not actually needed. Such solutions also give each memory vendor flexibility to optimize circuits and to control RFM requests per their specific row-hammer capability. It may be further appreciated that the techniques disclosed herein apply to any variety of DRAM such as LP4, LP5, DDR5, and HBM devices.

In the same preceding example, to request the refresh operation, the tracking module may be configured to indicate to a controller that the row-level activation count satisfies the row-level condition.

In one or more of the preceding two examples, the tracking module, to indicate to the controller that the row-level activation count satisfies the row-level condition, sets a flag at a location in the memory device checked by the controller.

In one or more of the preceding three examples, the tracking module, to indicate to the controller that the row-level activation count satisfies the row-level condition, sets a pin checked by the controller.

In one or more of the preceding four examples, the tracking module, to indicate to the controller that the row-level activation count satisfies the row-level condition, adjusts a refresh counter to prompt the controller to initiate the refresh operation.

The included descriptions and figures depict specific embodiments to teach those skilled in the art how to make and use the best mode. For the purpose of teaching inventive principles, some conventional aspects have been simplified or omitted. Those skilled in the art will appreciate variations from these embodiments that fall within the scope of the disclosure. Those skilled in the art will also appreciate that the features described above may be combined in various ways to form multiple embodiments. As a result, the invention is not limited to the specific embodiments described above, but only by the claims and their equivalents.

What is claimed is:

1. A computing apparatus comprising:
a memory device comprising:
banks of memory cells arranged in rows and columns;
a counter circuit connected to a row in the bank of memory cells, wherein the counter circuit is configured to increment a row-level activation count on a per-row basis; and
a request circuit configured to request a refresh operation for the row in the banks of memory cells, when the row-level activation count for the row satisfies a row-level condition; and
a controller operatively coupled with the memory device and configured to:
maintain a bank-level activation count on a per-bank basis; and
initiate a refresh operation for at least a given row in the memory device when at least both the bank-level activation count for a given bank satisfies a bank-level condition, and the row-level activation count for the given row satisfies a row-level condition.

2. The computing apparatus of claim 1 wherein the memory device is further configured to indicate to the controller that the row-level activation count satisfies the row-level condition.

3. The computing apparatus of claim 2 wherein the memory device, to indicate to the controller that the row-level activation count satisfies the row-level condition, sets a flag at a location in the memory device checked by the controller.

4. The computing apparatus of claim 3 wherein the controller is configured to check the flag when the bank-level activation count satisfies the bank-level condition.

5. The computing apparatus of claim 2 wherein the memory device, to indicate to the controller that the row-level activation count satisfies the row-level condition, sets a pin checked by the controller.

6. The computing apparatus of claim 5 wherein the controller is configured to check the pin when the bank-level activation count satisfies the bank-level condition.

7. The computing apparatus of claim 2 wherein the memory device, to indicate to the controller that the row-level activation count satisfies the row-level condition, adjusts a refresh counter to prompt the controller to initiate the refresh operation.

8. The computing apparatus of claim 1 wherein:
to initiate the refresh operation, the controller sends a refresh command to the memory device; and the memory device comprises dynamic random-access memory (DRAM) memory.

9. A memory device comprising:
banks of memory cells arranged in rows and columns;
a counter circuit connected to a row in the bank of memory cells, wherein the counter circuit is configured to increment a row-level activation count for the row in the bank of memory cells; and
a request circuit configured to request a refresh operation, for the row in the banks of memory cells, when the row-level activation count for the row satisfies a row-level condition.

10. The memory device of claim 9 wherein, to request the refresh operation, the request circuit is configured to indicate to a controller that the row-level activation count satisfies the row-level condition.

11. The memory device of claim 10 wherein the request circuit, to indicate to the controller that the row-level activation count satisfies the row-level condition, sets a flag at a location in the memory device checked by the controller.

12. The memory device of claim 10 wherein the request circuit, to indicate to the controller that the row-level activation count satisfies the row-level condition, sets a pin checked by the controller.

13. The memory device of claim 10 wherein the request circuit, to indicate to the controller that the row-level activation count satisfies the row-level condition, adjusts a refresh counter to prompt the controller to initiate the refresh operation.

14. A microprocessor comprising:
one or more processing units; and
a memory controller;
wherein the one or more processing units are configured to process data retrieved from one or more memory devices, and wherein each of the memory devices comprises:
banks of memory cells arranged in rows and columns;
a counter circuit connected to a row in the bank of memory cells, wherein the counter circuit is configured to increment a row-level activation count on a per-row basis; and
a request circuit configured to request a refresh operation, for the row in the bank of memory cells, when the row-level activation count for the row satisfies a row-level condition; and
wherein the memory controller is configured to:
maintain a bank-level activation count on a per-bank basis; and
initiate a refresh operation for at least a given row in a memory device of the memory devices when at least both the bank-level activation count for a given bank satisfies a bank-level condition, and the row-level activation count for the given row satisfies a row-level condition.

15. The microprocessor of claim 14 wherein the memory device supplies an indication to the memory controller that the row-level activation count satisfies the row-level condition.

16. The microprocessor of claim 15 wherein the memory controller is configured to obtain the indication that that the row-level activation count satisfies the row-level condition by reading a flag at a location in the memory device.

17. The microprocessor of claim 16 wherein the memory controller is configured to check the flag when the bank-level activation count satisfies the bank-level condition.

18. The microprocessor of claim 15 wherein the memory controller is configured to obtain the indication that that the row-level activation count satisfies the row-level condition by reading a pin set by the memory device.

19. The microprocessor of claim 18 wherein the memory controller is configured to check the pin when the bank-level activation count satisfies the bank-level condition.

20. The microprocessor of claim 15 wherein the memory controller is configured to obtain the indication that that the row-level activation count satisfies the row-level condition by reading a refresh counter adjusted by the memory device to prompt an early refresh operation.
